(19) United States
(12) Patent Application Publication
(10) Pub. No.: US 2025/0125763 A1
(43) Pub. Date: Apr. 17, 2025

(54) Rivetless Crossbar for Photovoltaic Modules

(71) Applicant: Maxeon Solar Pte. Ltd., Singapore (SG)

(72) Inventor: Nicholas Berry, Beaverton, OR (US)

(21) Appl. No.: 18/380,176

(22) Filed: Oct. 15, 2023

(51) Int. Cl. H02S 30/10; F16B 12/44

(52) U.S. Cl. CPC H02S 30/10; F16B 12/44

(57) ABSTRACT

A photovoltaic module crossbar is disclosed. The photovoltaic module crossbar includes a central portion, a first angled end portion extending from the central portion in a first direction and configured to incur deformations from a first component of a photovoltaic module frame that interlock with deformations in the first component of the photovoltaic module frame, and a second angled end portion extending from the central portion in a second direction and configured to incur deformations from a second component of the photovoltaic module frame that interlock with deformations in the second component of the photovoltaic module frame.

### TECHNICAL FIELD

Embodiments of the disclosure pertain to rivetless crossbars, and more particularly to rivetless crossbars for photovoltaic modules.

### BACKGROUND

A photovoltaic module or solar panel is a device that converts sunlight into electricity using photovoltaic (PV) cells. PV cells are made of materials that generate electrons when exposed to light. The ability of photovoltaic modules to withstand damage by rain, hail, heavy snow load, and cycles of heat and cold can vary by module design. Such damage can affect the performance of the photovoltaic modules. Damage such as cracked solar cells, can result in the underperformance of photovoltaic modules. Thus, many manufacturers seek to design photovoltaic modules that are structured to minimize such damage. A conventional photovoltaic module design utilizes a front glass coversheet and a polymer backsheet and includes copper interconnect wires between silicon cells. However, this design is sensitive to tensile stress related cracking of the PV cells when front side mechanical loads are applied to the photovoltaic module through handling, snow load, or wind load. Cracks that are initially closed may result in minimal power loss. However, over time, where cracks widen, metallization associated with the PV cells can become discontinuous across the cracks, leading to higher than desired degradation rates and risks of hot spot heating. Consequently, such photovoltaic module designs can result in photovoltaic modules that provide a less than satisfactory mechanical load performance.

### BRIEF DESCRIPTION OF THE DRAWINGS

FIG. 1A illustrates an exemplary operating environment of a rivetless photovoltaic module crossbar according to one embodiment.

FIG. 1B shows a side view of the photovoltaic module that includes a rivetless photovoltaic module crossbar according to one embodiment.

FIG. 1C shows the backsheet side view of photovoltaic module according to one embodiment.

FIG. 1D illustrates the alignment of the angled ends with the undersized slots according to one embodiment.

FIG. 1E illustrates the insertion of the angled ends through the undersized slots according to one embodiment.

FIG. 1F illustrates a stage of the rivetless crossbar installation process according to one embodiment.

FIG. 1G illustrates a stage of the rivetless crossbar installation process according to one embodiment.

FIG. 1H illustrates a stage of the rivetless crossbar installation process according to one embodiment.

FIG. 2 shows a flowchart of a method of forming a photovoltaic module crossbar according to one embodiment.

### DESCRIPTION OF THE EMBODIMENTS

Photovoltaic module crossbars that provide mechanical support to photovoltaic modules are described. It should be appreciated that although embodiments are described herein with reference to example rivetless crossbar implementations, the disclosure is applicable to rivetless crossbar implementations in general as well as other kinds of rivetless crossbar implementations. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

A photovoltaic module or solar panel is a device that converts sunlight into electricity by using photovoltaic (PV) cells. PV cells are made of materials that generate electrons when exposed to light. The ability of photovoltaic modules to withstand damage by rain, hail, heavy snow load, and cycles of heat and cold can vary by module design. Such damage can affect the performance of the photovoltaic modules. Damage such as cracked solar cells, can result in the underperformance of such photovoltaic modules. Thus, many manufacturers seek to design photovoltaic modules that are structured to minimize such damage. A conventional photovoltaic module design utilizes a front glass coversheet and a polymer backsheet and includes copper interconnect wires between silicon cells. However, this design is sensitive to tensile stress related cracking of the PV cells when front side mechanical loads are applied to the photovoltaic module through handling, snow load, or wind load. Cracks that are initially closed can result in minimal power loss. However, over time, where cracks widen, metallization associated with the PV cells can become discontinuous across the cracks, leading to higher than desired degradation rates and risks of hot spot heating. Consequently, such photovoltaic module designs can result in photovoltaic modules that provide a less than satisfactory mechanical load performance.

Approaches that overcome the challenges of the previous approaches are disclosed herein. As part of one embodiment, a photovoltaic module crossbar is disclosed. The photovoltaic module crossbar includes a central portion, a first angled end portion extending from the central portion in a first direction and configured to incur deformations from a first component of a photovoltaic module frame that interlock with deformations in the first component of the photovoltaic module frame, and a second angled end portion extending from the central portion in a second direction and configured to incur deformations from a second component of the photovoltaic module frame that interlock with deformations in the second component of the photovoltaic module frame.

### Rivetless Photovoltaic Module Crossbar

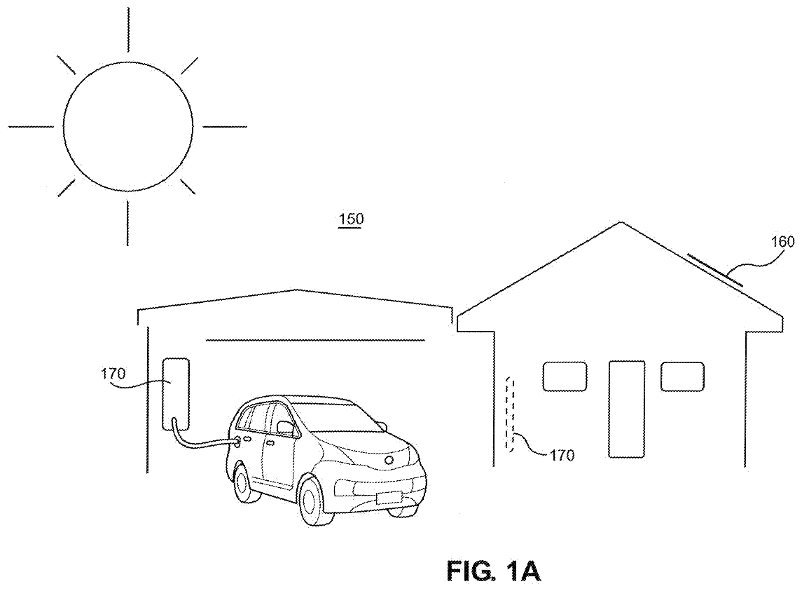

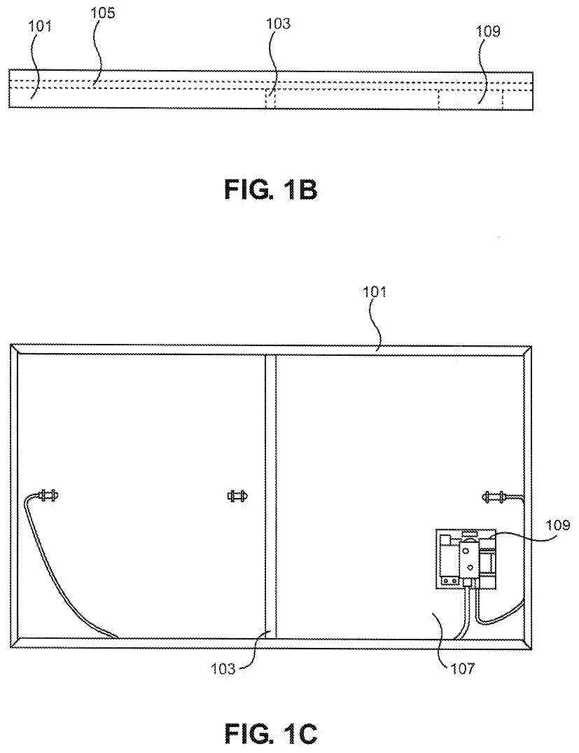

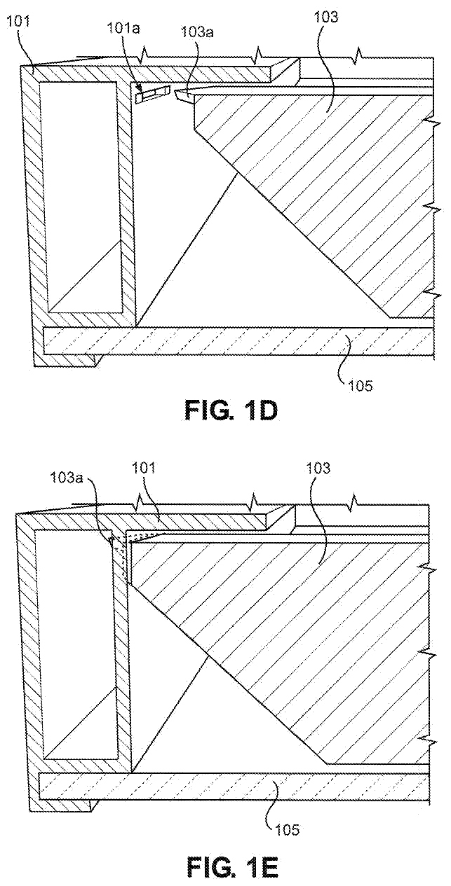

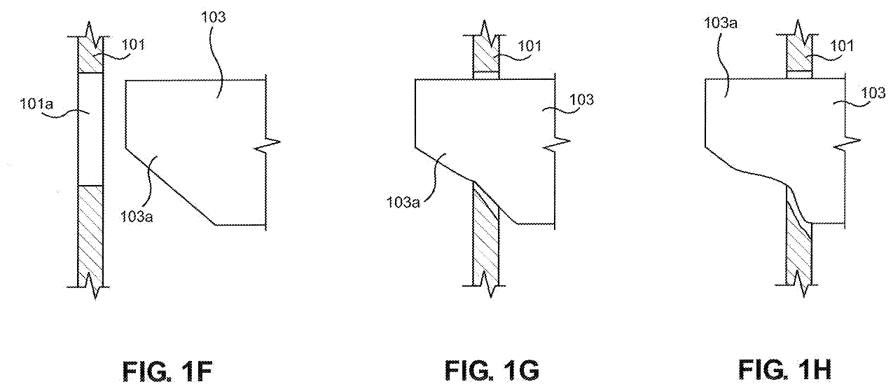

FIG. 1A illustrates an exemplary operating environment of a rivetless photovoltaic module crossbar according to one embodiment. FIG. 1A shows a location 150 that includes photovoltaic modules 100 that include rivetless photovoltaic module crossbars according to one embodiment. In one embodiment, the rivetless photovoltaic module crossbars provide mechanical load support for the photovoltaic modules 100, which generate electrical energy that is used to supply the location with electricity (e.g., to power appliances 170).

FIG. 1B shows a side view of the photovoltaic module 100 that includes a rivetless photovoltaic module crossbar according to one embodiment. FIG. 1A shows frame 101, crossbar 103, glass laminate 105, and optional AC inverter 109 (backsheet 107 not shown in FIG. 1A).

FIG. 1C shows the backsheet side view of photovoltaic module 100 according to one embodiment. FIG. 1C shows frame 101, crossbar 103, backsheet 107, and AC inverter 109 (optional) (glass laminate 105 not shown in FIG. 1C).

Referring to FIG. 1C, the frame 101 attaches components of the photovoltaic module 100 such as the glass laminate 105 (FIG. 1B). In one embodiment, the frame 101 includes undersized slots that receive angled ends of the crossbar 103 (the undersized slots of the frame 101 and the angled ends of the crossbar 103 are described below with reference to FIGS. 1D-1H). In other embodiments, undersized holes or other shaped openings in the frame 101 can be used. In one embodiment, rather than both ends, a single end of the crossbar can have an angled end. In one embodiment, the angled ends of the crossbar 103 are configured such that when forced into the undersized slots of the frame 101, deformations to the angled ends of the crossbar 103 and to the undersized slots of the frame 101 cause a fastening of the crossbar 103 to the frame 101. In one embodiment, the deformations to the undersized slots of the frame 101 caused by the angled ends of the crossbar 103 and the deformations to the angled ends of the crossbar 103 caused by surfaces of the undersized slots of the frame 101 interlock to affect a firm attachment of the crossbar 103 to the frame 101. In one embodiment, the crossbar 103 provides support to the frame that increases the capacity of the frame 101 to handle heavy mechanical loads. In one embodiment, the frame 101 can be formed from aluminum. In other embodiments, the frame 101 can be formed from other materials.

The crossbar 103 is an elongated and rigid beam with angled ends that is installed to extend across the backsheet side of the photovoltaic module 100 to provide mechanical load support to the photovoltaic module 100. In one embodiment, the crossbar 103 is coupled to first and second sides of the frame 101 of the photovoltaic module 100. In one embodiment, as part of the installation of the crossbar 103, the angled ends of the crossbar 103 are aligned with the undersized slots that are formed in the sides of the frame 101 and are caused by the exertion of a force on the shaft of the crossbar 103 to extend into the undersized slots. In one embodiment, the longest portions of the respective angled ends are longer than the length of the undersized slots that are formed in the sides of the frame 101 (or wider than holes if holes are used). FIGS. 1D and 1E illustrate the alignment of angled ends 103a with undersized slots 101a (FIG. 1D) and the insertion of the angled ends 103a into and through the undersized slots 101a (FIG. 1E). Referring to FIGS. 1D and 1E, in one embodiment, as described above, the angled ends 103a of the crossbar 103 are configured such that when forced into the undersized slots 101a of the frame 101 deformations to the angled ends 103a of the crossbar 103 and to the undersized slots 101a of the frame 101 cause a fastening of the crossbar 103 to the frame 101. In one embodiment, the deformations to the undersized slots 101a of the frame 101 caused by the angled ends 103a of the crossbar 103 and the deformations to the angled ends 103a of the crossbar 103 caused by surfaces of the undersized slots 101a of the frame 101 interlock to affect a firm attachment of the crossbar 103 to the frame 101.

Referring again to FIG. 1B, the glass laminate 105 can include components that include but are not limited to glass, encapsulant (front and back), and solar cells. In one embodiment, the glass laminate 105 is coupled to the frame 101 and is a surface upon which forces that can cause mechanical load stress are applied. In particular, weight on the glass laminate 105 that puts stress on the photovoltaic module 100. This force, along with forces that can act directly on the frame 101 of the photovoltaic module 100, can test the strength of the photovoltaic module 100. In one embodiment, stresses that can act on the frame 101 of the photovoltaic module 100 can include but are not limited to stresses from human handling, snow, and strong winds.

Referring to FIG. 1C, in one embodiment, the backsheet 107 provides electrical isolation of internal circuitry with the external environment. The backsheet 107 is formed on the backside of the glass laminate 105 of the photovoltaic module 100. The backside of the backsheet 107 is adjacent the top surface of the crossbar 103. A purpose of the backsheet 107 is to protect the photovoltaic module 100 from UV radiation, prevent moisture penetration, provide electrical insulation of the system, and to increase the durability of the photovoltaic module 100. As such, it plays a role in protecting the photovoltaic module 100 from harsh, varying environmental conditions. Mechanical load failures can cause damage to backsheets. And, damage to backsheets can cause a safety hazard. The installment of the crossbar 103 can provide the support that is needed to prevent load failure that can cause damage to the backsheet 107, glass laminate 105, or frame 101. In one embodiment, the backsheet 107 can be formed from a polymer or a combination of polymers. In other embodiments, the backsheet 107 can be formed from other materials.

AC inverter 109 is an electrical device that converts the direct current (DC) output from the photovoltaic system into alternating current (AC) of suitable voltage, frequency and phase for use by AC appliances and/or to export to a grid. Mechanical load failures can cause failure of electrical contacts, string interconnects, etc., that receive DC output from the photovoltaic module components and/or that deliver the generated AC to appliances or the grid. In one embodiment, the installment of the crossbar 103 as described herein can provide the support that is needed to prevent load failure that can cause the failure of these components.

In one embodiment, the crossbar 103 does not need screws or rivets to install. In one embodiment, the crossbar 103 can be placed on the center of the backsheet 107 before framing In one embodiment, a plurality of crossbars can be used. In one embodiment, an adhesive or tape can be attached to the backsheet 107 to hold one or more crossbar(s) in place during installation. In other embodiments, an adhesive or a tape may not be used to hold a crossbar in place during installation. In one embodiment, the adhesive can be a room temperature vulcanizing (RTV) adhesive. In other embodiments, other types of adhesives can be used. In one embodiment, during the framing process, the angled ends of the crossbar 103 are forced into slots on the inner side of the frame 101 in order to make an electrical and mechanical connection with the frame 101. In one embodiment, during the insertion of the angled ends of the crossbar 103 into the slots on the inner sides of the frame 101, the crossbar and frame will be deformed at the points of contact, as the angled ends are pressed further into the slots. The interlocking deformations of the crossbar and frame securely attach the crossbar 103 to the frame 101 and provide electrical contact between the crossbar and the frame 101 (which is required for grounding). In one embodiment, the design of the crossbar 103 reduces BOM cost and complexity. In one embodiment, the installation of the crossbar 103 can be integrated into the operation of framing equipment. In one embodiment, the manner of installation of the crossbar 103 can help to avoid the need for a separate framing station for the installation of rivets into the crossbar 103 and for the corresponding additional cycle time. In one embodiment, advantages include but are not limited to a reduction in BOM cost, labor, complexity of factory operations and cycle time in the factory (by simplifying installation in the factory). Consequently, embodiments can enable the photovoltaic module to be produced in a manner that is cost competitive.

### Operation

In operation, after installation, the crossbar 103 provides the photovoltaic module 100 with the mechanical support needed to ensure that the photovoltaic module 100 including the frame 101 and the glass laminate 105 has the capability to withstand mechanical loads that can be derived from sources that can include but are not limited to handling, wind, and snow that can be applied during shipping, installation, and in the field. In one embodiment, the crossbar 103 can provide a stiffening force that reduces deflections of the photovoltaic module that can be caused by mechanical loads. In one embodiment, this makes the photovoltaic module 100 less susceptible to damage such as stress related cracking of the PV cells when front side mechanical loads are present on the photovoltaic module. In particular, in one embodiment, the crossbar 103 is configured to provide a sufficient stiffening force to prevent or reduce crack formation due to front side mechanical loads and/or to slow the opening of cracks and the related power loss for cracks that do form. It should be appreciated that although cracks that are initially closed may result in minimal power loss, over time, in cases where those cracks widen, metallization associated with the PV cells can become discontinuous across the cracks, leading to higher than desired degradation rates and a risk of hot spot heating. In addition, the use of adhesive or tape as described herein can improve crossbar support during strong wind loads.

FIGS. 1F-1H show stages of the rivetless crossbar installation process according to one embodiment. As part of the installation process, as shown in FIG. 1F, initially the angled ends 103a are aligned with the undersized slots 101a located on the inside parts of the frame 101 before being inserted therein. After the tip of the angled ends 103a have been inserted into the undersized slots 101a located on the inside parts of the frame 101, the angled ends 103a are pressed further into the undersized slots 101a until the angled ends 103a have been fully pressed into the undersized slots 101a and a firm attachment of the rivetless crossbar to the frame is established. As the angled ends 103a move from an initial to a final position, the angled ends 103a and portions of the undersized slots 101a that contact the angled ends 103a are deformed as is illustrated in FIG. 1G and FIG. 1H. In particular, as the angled ends 103a move from an initial to a final position in the undersized slots 101a, the angled ends 103a incur deformations from the undersized slots 101a that interlock with deformations in the undersized slots 101a that are caused during the movement of the angled ends 103a from the initial to the final position.

### Method of Forming a Rivetless Photovoltaic Module Crossbar

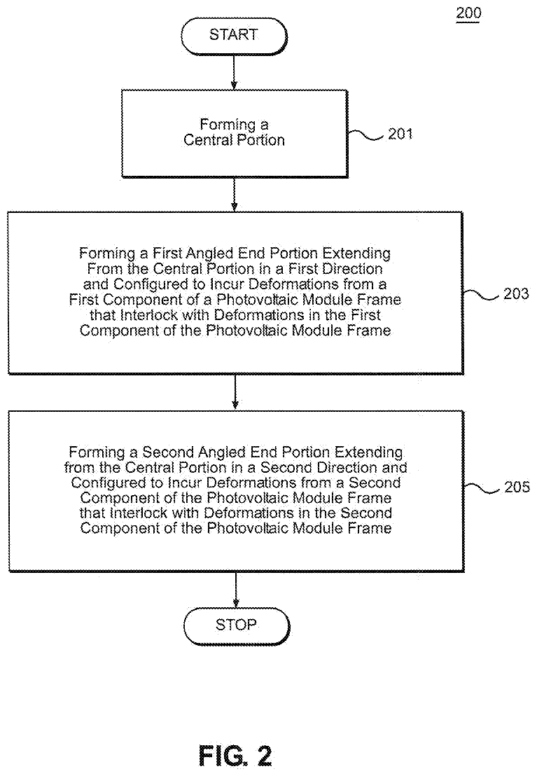

FIG. 2 shows a flowchart 200 of a method of forming a photovoltaic module crossbar according to one embodiment. Referring to FIG. 2, the method includes at 201, forming a central portion, at 203 forming a first angled end portion extending from the central portion in a first direction and configured to incur deformations from a first component of a photovoltaic module frame that interlock with deformations in the first component of the photovoltaic module frame, and, at 205, forming a second angled end portion extending from the central portion in a second direction and configured to incur deformations from a second component of the photovoltaic module frame that interlock with deformations in the second component of the photovoltaic module frame. In one embodiment, a single end of the crossbar can be formed to have the angled shape (making 205 optional).

In one embodiment, the deformations in the first angled end and the deformations in the second angled end attach the photovoltaic module crossbar to the photovoltaic module frame. In one embodiment, the first angled end and the second angled end make electrical and mechanical contact with the photovoltaic module frame. In one embodiment, the photovoltaic module frame includes a rectangular tube. In other embodiments, the photovoltaic module frame can include an I-beam. In still other embodiments, the photovoltaic module frame can include other shapes. In one embodiment, the crossbar is adjacent to a backsheet of the photovoltaic module. In one embodiment, the first component is a slot (or hole or other shape) on a first inner side of the photovoltaic module frame. In one embodiment, the second component is a slot (or hole or other shape) on a second inner side of the photovoltaic module frame. In one embodiment, portions of the frame on both sides of the photovoltaic module can be pushed as part of the installation process. In other embodiments, portions of the frame on both sides of the photovoltaic module may not be pushed as part of the installation process.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure. The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of the different embodiments may be variously combined with some features included and others excluded to suit a variety of different applications.

What is claimed is:

1. A photovoltaic module crossbar, comprising:
a central portion;
a first angled end portion extending from the central portion in a first direction and configured to incur deformations from a first component of a photovoltaic module frame that interlock with deformations in the first component of the photovoltaic module frame; and
a second angled end portion extending from the central portion in a second direction and configured to incur deformations from a second component of the photovoltaic module frame that interlock with deformations in the second component of the photovoltaic module frame.

2. The photovoltaic module crossbar of claim 1, wherein the deformations in the first angled end portion and the deformations in the second angled end portion attach the photovoltaic module crossbar to the photovoltaic module frame.

3. The photovoltaic module crossbar of claim 1, wherein the first angled end portion and the second angled end portion make electrical and mechanical contact with the photovoltaic module frame.

4. The photovoltaic module crossbar of claim 1, wherein the photovoltaic module frame includes a rectangular portion.

5. The photovoltaic module crossbar of claim 1, wherein the crossbar is adjacent to a backsheet of the photovoltaic module.

6. The photovoltaic module crossbar of claim 1, wherein the first component is a slot on a first inner side of the photovoltaic module frame.

7. The photovoltaic module crossbar of claim 1, wherein the second component is a slot on a second inner side of the photovoltaic module frame.

8. A photovoltaic module, comprising:
a photovoltaic module frame; and
a photovoltaic module crossbar coupled to the photovoltaic module frame, comprising:
a central portion;
a first angled end portion extending from the central portion in a first direction and configured to incur deformations from a first component of a photovoltaic module frame that interlock with deformations in the first component of the photovoltaic module frame; and
a second angled end portion extending from the central portion in a second direction and configured to incur deformations from a second component of the photovoltaic module frame that interlock with deformations in the second component of the photovoltaic module frame.

9. The photovoltaic module crossbar of claim 8, wherein the deformations in the first angled end portion and the deformations in the second angled end portion attach the photovoltaic module crossbar to the photovoltaic module frame.

10. The photovoltaic module crossbar of claim 8, wherein the first angled end portion and the second angled end portion make electrical and mechanical contact with the photovoltaic module frame.

11. The photovoltaic module crossbar of claim 8, wherein the photovoltaic module frame includes a rectangular tube.

12. The photovoltaic module crossbar of claim 8, wherein the crossbar is adjacent to a backsheet of the photovoltaic module.

13. The photovoltaic module crossbar of claim 8, wherein the first component is a slot on a first inner side of the photovoltaic module frame.

14. The photovoltaic module crossbar of claim 8, wherein the second component is a slot on a second inner side of the photovoltaic module frame.

15. A method of forming a photovoltaic module crossbar, comprising:
forming a central portion;
forming a first angled end portion extending from the central portion in a first direction and configured to incur deformations from a first component of a photovoltaic module frame that interlock with deformations in the first component of the photovoltaic module frame; and
forming a second angled end portion extending from the central portion in a second direction and configured to incur deformations from a second component of the photovoltaic module frame that interlock with deformations in the second component of the photovoltaic module frame.

16. The method of forming a photovoltaic module crossbar of claim 15, wherein the deformations in the first angled end portion and the deformations in the second angled end portion attach the photovoltaic module crossbar to the photovoltaic module frame.

17. The method of forming a photovoltaic module crossbar of claim 15, wherein the first angled end portion and the second angled end portion make electrical and mechanical contact with the photovoltaic module frame.

18. The method of forming a photovoltaic module crossbar of claim 15, wherein the photovoltaic module frame includes a rectangular tube.

19. The method of forming a photovoltaic module crossbar of claim 15, wherein the crossbar is adjacent to a backsheet of the photovoltaic module.

20. The method of forming a photovoltaic module crossbar of claim 15, wherein the first component is a slot on a first inner side of the photovoltaic module frame.
